(19) United States
(12) Patent Application Publication
(10) Pub. No.: US 2008/0308854 A1
(43) Pub. Date: Dec. 18, 2008

(54) SEMICONDUCTOR MEMORY DEVICE AND FABRICATION METHOD THEREOF

(75) Inventor: Yoshihiro TAKAISHI, Tokyo (JP)

Correspondence Address: YOUNG & THOMPSON, 209 Madison Street, Suite 500, ALEXANDRIA, VA, 22314, US

(73) Assignee: ELPIDA MEMORY, INC., TOKYO (JP)

(21) Appl. No.: 12/138,632

(22) Filed: Jun. 13, 2008

(30) Foreign Application Priority Data
Jun. 15, 2007 (JP) P2007-159276

(51) Int. Cl. H01L 27/108; H01L 21/02

(52) U.S. Cl. 257/304; 438/386; 257/E27.092; 257/E21.011

(57) ABSTRACT

A semiconductor memory device including a cylinder hole extended in a thickness direction of an insulating film; a capacitor configured from a lower electrode, which is formed on an inner surface of the cylinder hole, and an upper electrode, which is formed on a surface of the lower electrode via a capacitance insulating film; and a capacitance contact plug which is embedded in the insulating film and a portion thereof is exposed inside the cylinder hole so as to be electrically connected with the lower electrode due to the lower electrode covering a surface of this exposed portion, wherein the capacitance contact plug is provided by the portion, which is exposed inside the cylinder hole, being extended from a bottom portion side towards an upper portion side of the cylinder hole.

### BACKGROUND OF THE INVENTION

1. Field of the Invention

The present invention relates to a semiconductor memory device and a fabrication method thereof, and particularly relates to a miniaturization technology of a semiconductor memory device having a dynamic random access memory (DRAM) capacitor.

Priority is claimed on Japanese Patent Application No. 2007-159276, filed Jun. 15, 2007, the content of which is incorporated herein by reference.

2. Description of the Related Art

As integrated circuits become more refined and highly integrated with a higher level of performance, the cell size of DRAM is also reduced, and thus it is becoming difficult to secure the cell capacity required for the DRAM operation. Examples of means to increase cell capacity include:

(1) Increasing the area of a capacity section;

(2) Reducing the film thickness of a capacitance insulating film; and

(3) Increasing the dielectric constant of the capacitance insulating film.

The cell capacity has been secured in the past by combining the above solutions (1) to (3).

Of these, production of a 3 dimensional lower electrode in a capacity section is generally adopted as the method to achieve the solution (1) to increase the area of a capacity section, and typical examples thereof include a method to make the capacity section into a deep-holed inner-walled cylindrical structure (for example, Patent Document 1). This is a method in which a deep hole is formed in an interlayer insulating film and then a capacity section having a cylindrical structure is formed therein. As shown in FIG. 18, in a semiconductor memory device having a cylindrical structure disclosed in Patent Document 1, a first interlayer insulating film 73, a stopper nitride film 74, and a second interlayer insulating film 75 are laminated in order on a semiconductor substrate 71, in which a transistor 72 is formed. A capacitance contact plug 76 is embedded in the first interlayer insulating film 73. A deep hole for a cylinder (capacitor hole) 77 is provided in the stopper nitride film 74 and in the second interlayer insulating film 75 by penetrating the films, and the capacitance contact plug 76 is exposed at a bottom portion of the hole. In addition, on the internal surface and on the bottom surface of the deep hole for a cylinder 77, a lower electrode 78, a capacitance insulating film 79, and an upper electrode 80 are laminated in this order. A capacitor is configured by the lower electrode 78 being electrically connected with the capacitance contact plug 76, which is exposed at the bottom portion of the deep hole for a cylinder 77.

In such a deep-holed inner-walled cylindrical structure, by making the depth of the deep hole for a cylinder 77 even deeper. In other words, by making the height of the lower electrode 78 even higher, the capacitor area can be increased for the sake of securing an even larger cell capacity.

On the other hand, a method, in which the dielectric constant of a capacitance insulating film is increased so as to reduce the electrical film thickness thereof, is adopted to achieve the abovementioned solutions (2) and (3). In addition, in order to achieve further reductions in the film thickness of a capacitance insulating film, a metal-insulator-semiconductor (MIS) structure, in which the lower electrode is formed of polysilicon, is generally replaced by a metal-insulator-metal (MIM) structure, which employs a metal instead of a polysilicon. In the MIS structure, since the lower electrode is formed of polysilicon, a silicon oxide (SiO₂) film is generated between the lower electrode and the capacitance insulating film making the effective electrical film thickness of the capacitance insulating film thick. On the other hand, by forming the lower electrode with a metal, a parasitic insulating film is not generated at the interface with a capacitance insulating film, thereby enabling further reductions in the electrical film thickness of the capacitance insulating film. [Patent Document 1] Japanese Patent Application, First Publication No. 2004-172474

Incidentally, when cell size is miniaturized, it will become necessary to secure the area of a region, in which a capacity section is provided, as much as possible. Accordingly, a capacitor over bit line structure (COB structure) where a capacity section is disposed on a bit line is generally adopted.

The following problem arises when attempting to secure capacity by the method (1) in such a COB structure.

That is, as the depth of a cylinder hole in the capacity section deepens, the depth of a through hole, which links the bit line provided below the cylinder hole and the A1 line provided above the cylinder hole, also deepens. In other words, due to the arrangement of the bit line and the A1 line, the through hole is always at least 500 nm deeper than the cylinder hole. For this reason, as the depth of the cylinder hole deepens, processing of the through hole will first become more difficult than the processing of a hole for forming the cylindrical structure, which is a problem. Moreover, as the depth of the through hole deepens (i.e., as the aspect ratio increases), it will become difficult to form a contact plug with good coverability inside the through hole, thereby increasing the contact resistance between the formed contact plug and the lines, which is a problem.

Additionally, when the MIM structure is adopted as a structure of the capacity section, increase in the contact resistance between the capacitance contact plug and the metal lower electrode of the capacity section will be a problem. Especially when the height of the cylinder hole increases (when the hole deepens), a metal film, which is to become the lower electrode, will be formed inside a hole having a high aspect ratio. Accordingly, it will be highly difficult to form the lower electrode on the upper surface of the capacitance contact plug, which is exposed at the bottom surface of this hole, with a satisfactory coverability. For this reason, it is difficult to achieve a stable contact resistance between the capacitance contact plug and the metal lower electrode of the capacity section.

The present invention is made in view of the above circumstances and the object thereof is to provide a semiconductor memory device and a fabricating method thereof that are, even when the cylinder hole has a high aspect ratio, capable of reducing the contact resistance between the capacitance contact plug and the lower electrode, capable of stably forming a through hole, which connects the line arranged below the capacity section and the line arranged above the capacity section, and also capable of reducing the contact resistance between a through hole plug, which is provided in the through hole, and the lines.

### SUMMARY OF THE INVENTION

In order to solve the above problems, the semiconductor memory device of the present invention is characterized by including a cylinder hole extended in a thickness direction of an insulating film; a capacitor configured from a lower electrode, which is formed on an inner surface of the cylinder hole, and an upper electrode, which is formed on a surface of the lower electrode via a capacitance insulating film; and a capacitance contact plug which is embedded in the insulating film and a portion thereof is exposed inside the cylinder hole so as to be electrically connected with the lower electrode due to the lower electrode covering a surface of this exposed portion, wherein the capacitance contact plug is provided by the portion, which is exposed inside the cylinder hole, being extended from a bottom portion side towards an upper portion side of the cylinder hole.

According to this configuration, even when the cylinder hole has a high aspect ratio, it is possible to reduce the contact resistance between the capacitance contact plug and the lower electrode, to stably form a through hole, which connects the line arranged below the capacitor and the line arranged above the capacitor, and to reduce the contact resistance between a through hole plug, which is provided in the through hole, and the lines.

In the present invention, it is preferable that the cylinder hole have a tapered surface in an internal surface thereof and that an end face of the capacitance contact plug is exposed along the tapered surface.

In the present invention, it is preferable that the end face of the capacitance contact plug is exposed throughout from one end portion of the tapered surface to another.

In the present invention, it is preferable that the end face of the capacitance contact plug is inscribed in an opening of the cylinder hole when seen in plan view.

In the present invention, it is preferable that the portion of the capacitance contact plug exposed inside the cylinder hole is protruding from a bottom portion of the cylinder hole.

According to these configurations, a sufficient contact area between the capacitance contact plug and the lower electrode can be achieved, and thus the contact resistance therebetween can reliably be reduced.

In the present invention, it is preferable to include a peripheral circuit region, which has, around a region where the capacitor is provided, a transistor for a peripheral circuit and a first line that are embedded in the insulating film, and a second line arranged on the insulating film, and the peripheral circuit region includes a contact plug, which is provided in the same forming process as a process for forming the capacitance contact plug, on the first line.

According to this configuration, it is possible to reduce the height of the through hole plug, which connects the first and the second lines, by the length equivalent to the height of the contact plug. As a result, the aspect ratio of the through hole decreases, and thus the through hole can stably be formed. In addition, the contact resistance between the through hole plug, which is provided inside the through hole, and the lines can also be reduced.

In the present invention, it is preferable that the insulating film include an etching stopper film, which controls a position to stop an etching process when forming the cylinder hole by the etching process, and the capacitance contact plug intersects with the etching stopper film and is extended in a surface side of the insulating film.

According to this configuration, the height of the capacitance contact plug can be further increased. Accordingly, it will be possible to sufficiently expose the capacitance contact plug in the contact hole and to further increase the contact area between the capacitance contact plug and the lower electrode. Moreover, when a contact plug is provided in the peripheral circuit region in parallel to the capacitance contact plug in the same forming process, height of this contact plug can also be increased further, and thus the height of the through hole can be decreased by the same extent. As a result, the aspect ratio of the through hole reduces, and thus the through hole can be formed even more stably. In addition, the contact resistance between the through hole plug, which is provided inside the through hole, and the lines can also be reduced even further.

The method for fabricating the semiconductor memory device of the present invention is a method for fabricating a semiconductor memory device including a cylinder hole extended in a thickness direction of an insulating film, a capacitor configured from a lower electrode, which is formed on an inner surface of the cylinder hole, and an upper electrode, which is formed on a surface of the lower electrode via a capacitance insulating film, and a capacitance contact plug which is embedded in the insulating film and a portion thereof is exposed inside the cylinder hole so as to be electrically connected with the lower electrode due to the lower electrode covering a surface of this exposed portion. The method is characterized by including the steps of forming an interlayer insulating film, which is provided on a semiconductor substrate, an etching stopper film, which controls a position to stop an etching process when forming the cylinder hole by the etching process, and, on a first cylinder interlayer insulating film, the capacitance contact plug, which penetrates these films; forming a second cylinder interlayer insulating film on the first cylinder interlayer insulating film and on the capacitance contact plug; forming a first cylinder hole in a region containing a portion which corresponds to the capacitance contact plug of the second cylinder interlayer insulating film by subjecting the region to an etching process to penetrate so that the internal surface of the first cylinder hole is almost perpendicular to a surface of the second cylinder interlayer insulating film, and exposing an end face of the capacitance contact plug; and forming a second cylinder hole which has a tapered internal surface so as to be continuous with the first cylinder hole by at least subjecting the etching stopper film, the first cylinder interlayer insulating film, and the capacitance contact plug to an etching process, and exposing the end face of the capacitance contact plug along the tapered internal surface.

According to this configuration, even when the cylinder hole has a high aspect ratio, it is possible to fabricate a semiconductor memory device which is capable of reducing the contact resistance between the capacitance contact plug and the lower electrode, capable of stably forming a through hole, which connects the line arranged below the capacitor and the line arranged above the capacitor, and capable of reducing the contact resistance between a through hole plug, which is provided in the through hole, and the lines.

The method for fabricating the semiconductor memory device of the present invention is a method for fabricating a semiconductor memory device including a cylinder hole extended in a thickness direction of an insulating film, a capacitor configured from a lower electrode, which is formed on an inner surface of the cylinder hole, and an upper electrode, which is formed on a surface of the lower electrode via a capacitance insulating film, and a capacitance contact plug which is embedded in the insulating film and a portion thereof is exposed inside the cylinder hole so as to be electrically connected with the lower electrode due to the lower electrode covering a surface of this exposed portion. The method is characterized by including the steps of forming an interlayer insulating film, which is provided on a semiconductor substrate, an etching stopper film, which controls a position to stop an etching process when forming the cylinder hole by the etching process, and, on a first cylinder interlayer insulating film, the capacitance contact plug, which penetrates these films; forming a second cylinder interlayer insulating film on the first cylinder interlayer insulating film and on the capacitance contact plug; and forming the cylinder hole at least in the etching stopper film, the first cylinder interlayer insulating film, and in a region containing a portion which corresponds to the capacitance contact plug of the second cylinder interlayer insulating film by an etching process to penetrate these films under a condition where the etching rate for the respective interlayer insulating films and for the etching stopper film is higher than the etching rate for the capacitance contact plug, and making the portion of the cylinder hole protrude from a bottom portion of the cylinder hole.

According to this configuration, even when the cylinder hole has a high aspect ratio, it is possible to fabricate a semiconductor memory device which is capable of reducing the contact resistance between the capacitance contact plug and the lower electrode, capable of stably forming a through hole, which connects the line arranged below the capacitor and the line arranged above the capacitor, and capable of reducing the contact resistance between a through hole plug, which is provided in the through hole, and the lines.

In the present invention, it is preferable that at least one of the first cylinder interlayer insulating film and the second cylinder interlayer insulating film be formed into a laminated structure.

According to this configuration, a cylinder hole can be formed by forming a hole in each insulating film which constitutes the lamination structure. In this case, the depth of the holes formed in each insulating film can be set small, thereby enabling the stable formation of the holes with a predetermined size. As a result, a deep cylinder hole can be stably formed.

In the present invention, which is a method for producing a semiconductor memory device including a transistor for peripheral circuit and a first line, which are embedded in the insulating film, and a second line arranged on the insulating film, around a region where the capacitor is formed, it is preferable to form a contact plug in parallel to the step for forming the capacitance contact plug in portions corresponding to the interlayer insulating film of the peripheral circuit region, the etching stopper film, and a bit line of the first cylinder interlayer insulating film, so that the contact plug penetrates these films.

According to this configuration, it is possible to reduce the height of the through hole plug, which connects the first and the second lines, by the length equivalent to the height of the contact plug. As a result, the aspect ratio of the through hole reduces, and thus the through hole can stably be formed. In addition, the contact resistance between the through hole plug, which is provided inside the through hole, and the lines can also be reduced.

According to the present invention, since the capacitance contact plug is exposed in the cylinder holes by being extended from the bottom portion side to the opening side of the cylinder holes, sufficient contact area with respect to the capacitance lower electrode which is formed on the internal surface of the cylinder holes and on the surface of the capacitance contact plug exposed inside the cylinder holes can be secured. Due to the above configurations, it is possible to reduce the contact resistance between the capacitance contact plug and the lower electrode. Moreover, since the surface of the capacitance contact plug exposed in the cylinder holes is wide, it is possible to form the capacitance lower electrode which has a suitable coverability with respect to the exposed surface of the capacitance contact plug. Due to the above reasons, it will be possible to achieve a stable contact resistance between the capacitance contact plug and the capacitance lower electrode.

In addition, by forming the contact plug on a first line, which is embedded in an insulating film of the peripheral circuit region, in parallel to the process for forming the above capacitance contact plug, it is possible to reduce the height of the through hole plug, which connects the first line and a second line provided on the insulating film, by the length equivalent to the height of the contact plug. Due to this configuration, even when the depth of the cylinder holes deepens (i.e., even when the thickness of the insulating film increases), the aspect ratio of the through hole, which is provided for forming a through hole plug, can be reduced down to a relatively low level. As a result, the through hole plug can be formed stably in the through hole, and the contact resistance between the through hole plug and the respective lines can be reduced.

In addition, since this capacitance contact plug provided in the peripheral circuit region can be formed in parallel to the capacitance contact plug in the cell region, the aforementioned effects can be achieved without increasing the number of fabricating processes.

Due to the above reasons, a semiconductor memory device which is highly reliable can be achieved due to a simple fabrication process according to the present invention.

### BRIEF DESCRIPTION OF THE DRAWINGS

FIG. 1 is a plan view showing a semiconductor memory device of a first embodiment.

FIG. 2 is a longitudinal section showing the semiconductor memory device of the first embodiment.

FIG. 3 is a diagram showing a method for fabricating the semiconductor memory device of the first embodiment in the order of processes and is a longitudinal section showing a process for forming a transistor and a cell contact plug.

FIG. 4 is a diagram showing a method for fabricating the semiconductor memory device of the first embodiment in the order of processes and is a longitudinal section showing a bit line forming process.

FIG. 5 is a diagram showing a method for fabricating the semiconductor memory device of the first embodiment in the order of processes and is a longitudinal section showing a process for forming a second interlayer insulating film, a cylinder stopper nitride film, and a first cylinder interlayer insulating film.

FIG. 6 is a diagram showing a method for fabricating the semiconductor memory device of the first embodiment in the order of processes and is a longitudinal section showing a process for forming a capacitance contact plug.

FIG. 7 is a diagram showing a method for fabricating the semiconductor memory device of the first embodiment in the order of processes and is a longitudinal section showing a process for forming a second cylinder interlayer insulating film.

FIG. 8 is a diagram showing a method for fabricating the semiconductor memory device of the first embodiment in the order of processes and is a longitudinal section showing a cylinder hole forming process.

FIG. 9 is a diagram showing a method for fabricating the semiconductor memory device of the first embodiment in the order of processes and is a longitudinal section showing a process for forming a capacitance lower electrode.

FIG. 10 is a diagram showing a method for fabricating the semiconductor memory device of the first embodiment in the order of processes and is a longitudinal section showing a process for forming a capacitance insulating film, a capacitance upper electrode, and a third interlayer insulating film.

FIG. 11 is a diagram showing a method for fabricating the semiconductor memory device of the first embodiment in the order of processes and is a longitudinal section showing a process for forming a through hole plug.

FIG. 12 is a longitudinal section showing a semiconductor memory device of a second embodiment.

FIG. 13 is a diagram showing a method for fabricating the semiconductor memory device of the second embodiment in the order of processes and is a longitudinal section showing a cylinder hole forming process.

FIG. 14 is a diagram showing the order of the processes of a method for fabricating the semiconductor memory device of the second embodiment and is a longitudinal section showing a process for forming a capacitance lower electrode.

FIG. 15 is a drawing of longitudinal section showing a semiconductor memory device of a third embodiment.

FIG. 16 is a diagram showing the order of the processes of a method for fabricating the semiconductor memory device of the third embodiment and is a longitudinal section showing a cylinder hole forming process.

FIG. 17 is a diagram showing the order of the processes of a method for fabricating the semiconductor memory device of the third embodiment and is a longitudinal section showing a process for forming a capacitance lower electrode.

FIG. 18 is a longitudinal section showing a conventional semiconductor memory device.

### DETAILED DESCRIPTION OF THE INVENTION

A semiconductor memory device and a method for fabricating the device of the present invention will be described below in detail with reference to the attached diagrams.

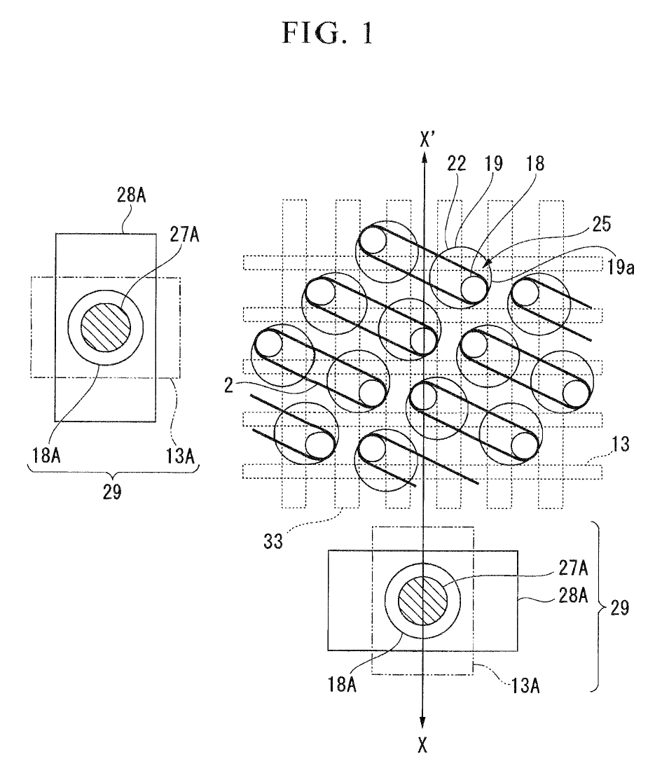

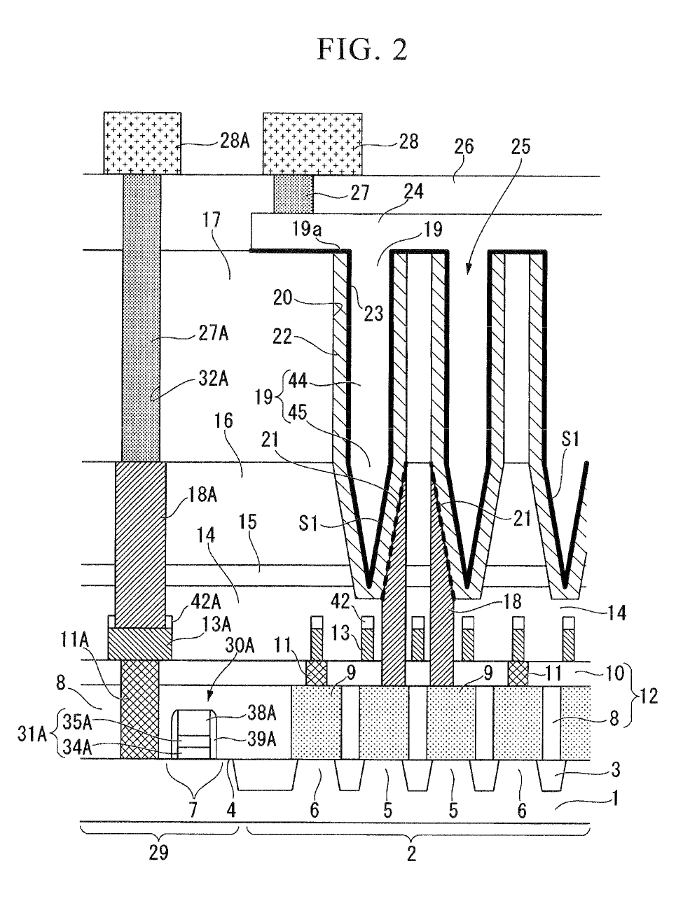

FIG. 1 is a plan view showing a first embodiment of a semiconductor memory device of the present invention. FIG. 2 is an enlarged longitudinal section of the semiconductor memory device shown in FIG. 1 as seen along the line X-X′.

As shown in FIG. 1, the semiconductor memory device has a plurality of cell regions 2 provided in a predetermined field, and a peripheral circuit region 29 arranged around the field. A plurality of bit lines 13 in a stripe pattern are provided in the field where the cell regions 2 are provided. In addition, a plurality of word lines 33 in a stripe pattern are provided in a manner so that they are perpendicular to the bit lines 13.

In the present embodiment, each of the cell regions 2 is shown as an example of a ¼ pitch layout arrangement that is provided diagonally with respect to the bit lines 13 when seen in plan view. Each of the cell regions 2 have two capacitors 25 provided in the cylinder hole 19, and a capacitance lower electrode 22 in each of the capacitors 25 is electrically connected with a capacitance contact plug 18. The capacitance contact plug 18 is provided so that the upper end face thereof is inscribed in an opening 19a of the cylinder hole 19 when seen in plan view. In addition, each of the capacitance contact plug 18 is provided in a position so as not to overlap with either the bit lines 13 or the word lines 33 when seen in plan view, and one of the capacitance contact plug 18 is arranged so as to sandwich one bit line 13 and two word lines 33 with another capacitance contact plug 18.

Configurations of the cell regions 2 and the peripheral circuit region 29 will be described individually below.

As shown in FIG. 2, the semiconductor memory device includes a silicon substrate 1.

In the cell region 2, the silicon substrate 1 has a plurality of active regions partitioned by a plurality of device isolation regions 3, and two transistors for selection are provided in each of the active regions. It should be noted that since FIG. 2 is a longitudinal section of the semiconductor memory device as seen along the line X-X′ in FIG. 1, only diffusion regions 5 and 6 and a gate oxide film 4 are shown among the components configuring the transistors for selection, and a gate electrode portion is not depicted here.

Each of the transistors for selection is configured from a gate electrode formed on the silicon substrate 1 via the gate oxide film 4, and a pair of diffusion regions 5 and 6 provided near the surface of the silicon substrate 1. The pair of diffusion layers 5 and 6 constitute a source region and a drain region, respectively. The two transistors for selection share this diffusion layer 6 which constitutes the drain region. In other words, the diffusion layer 6 functions as a drain region for two transistors for selection.

An interlayer insulating film 8 is provided on the silicon substrate 1 so as to cover the transistors for selection. Cell contact plugs 9 are provided by penetrating the interlayer insulating film 8 at positions corresponding to those of diffusion regions 5 and 6, and are connected with the diffusion regions 5 and 6.

An interlayer insulating film 10 is provided above the interlayer insulating film 8 and the cell contact plugs 9. Bit contact plugs 11 are provided by penetrating the interlayer insulating film 10 at positions corresponding to the cell contact plugs 9, which are connected with the diffusion regions 6, and are connected with the cell contact plugs 9.

Note that the interlayer insulating film 8 and the interlayer insulating film 10 are collectively referred to herein as a first interlayer insulating film 12.

Bit lines 13 are provided with a predetermined pattern above the interlayer insulating film 10 and the bit contact plugs 11. These bit lines 13 are electrically connected with the diffusion regions 6 via the bit contact plugs 11 and the cell contact plugs 9.

Additionally, a second interlayer insulating film 14 is provided above the interlayer insulating film 10 so as to cover the bit lines 13. A cylinder stopper nitride film 15, a first cylinder interlayer insulating film 16, and a second cylinder interlayer insulating film 17 are provided in order on the second interlayer insulating film 14.

Capacitance contact plugs 18 are provided by penetrating the interlayer insulating film 10, the second interlayer insulating film 14, the cylinder stopper nitride film 15, and the first cylinder interlayer insulating film 16, at positions corresponding to the cell contact plugs 9, which are connected with the diffusion regions 5, and the capacitance contact plugs 18 are connected with the cell contact plugs 9.

In addition, cylinder holes 19 are provided by penetrating the cylinder stopper nitride film 15, the first cylinder interlayer insulating film 16, and the second cylinder interlayer insulating film 17. Note that the cylinder holes 19 are provided herein so that the lower end face thereof enters the second interlayer insulating film 14 to some extent. In the second cylinder interlayer insulating film 17, the cylinder holes 19 have an internal surface 20 being substantially perpendicular to the upper surface of the second cylinder interlayer insulating film 17. On the other hand, in the second interlayer insulating film 14, the cylinder stopper nitride film 15, and the first cylinder interlayer insulating film 16, the internal surface of these cylinder holes 19 is a tapered surface 21.

At the tapered surface 21 of the cylinder holes 19, the upper end face of the capacitance contact plugs 18 is exposed in almost an elliptical shape with a length at least as long as the thickness of the cylinder stopper nitride film 15 and the first cylinder interlayer insulating film 16 put together, so as to be in line with the tapered surface 21.

In addition, on the internal surface of the cylinder holes 19 and on the surface of the capacitance contact plugs 18 exposed inside the cylinder holes 19 (exposed surface S1), the capacitance lower electrode 22 and a capacitance insulating film 23 are formed in order. A capacitance upper electrode 24 is provided on this capacitance insulating film 23 so as to fill in the cylinder holes 19. The capacitance lower electrode 22 is connected with the capacitance contact plugs 18, and is electrically connected with the diffusion regions 5 via the capacitance contact plugs 18 and the cell contact plugs 9. In the semiconductor memory device of the present embodiment, a capacitor 25 is configured from the capacitance lower electrode 22, the capacitance insulating film 23, and the capacitance upper electrode 24.

In this semiconductor memory device, particularly in the cylinder holes 19, the capacitance contact plugs 18 are exposed in almost an elliptical shape with a length at least as long as the thickness of the cylinder stopper nitride film 15 and the first cylinder interlayer insulating film 16 put together. Accordingly, this semiconductor memory device has an exposed surface S1 inside the cylinder holes which is wider than the capacitance contact plugs exposed at the bottom surface of the cylinder holes in the conventional semiconductor memory device. Hence, a sufficient contact area with the capacitance lower electrode 22 formed thereon can be secured, and thus the contact resistance between the capacitance contact plug 18 and the capacitance lower electrode 22 can be reduced. In addition, due to the wide exposed surface S1 of the capacitance contact plug 18, it is possible to form the capacitance lower electrode 22 on the exposed surface S1 of this capacitance contact plug 18 with a good coverability. Due to the above configuration, it will be possible to achieve a stable contact resistance between the capacitance contact plug 18 and the capacitance lower electrode 22.

A third interlayer insulating film 26 is provided above the second cylinder interlayer insulating film 17 and the capacitance upper electrode 24. In this third interlayer insulating film 26, a through hole plug 27 is provided by penetrating the film at the position corresponding to the capacitance upper electrode 24 so as to be connected with the capacitance upper electrode 24.

In addition, a line layer 28 with a predetermined pattern is provided above the third interlayer insulating film 26 and the through hole plug 27. This line layer 28 is electrically connected with the capacitance upper electrode 24 via the through hole plug 27.

On the other hand, in the peripheral circuit region 29, a transistor 30A for peripheral circuit is provided on the silicon substrate 1 in the active region partitioned by the device isolation region 2.

The transistor 30A for peripheral circuit is configured from a gate electrode 31A formed on the silicon substrate 1 via the gate electrode film 4 and a pair of diffusion regions 7 provided close to the surface of the silicon substrate 1.

A first interlayer insulating film 12 is provided on the silicon substrate 1 so as to cover the transistor 30 for a peripheral circuit. A bit contact plug 11A is provided in this first interlayer insulating film 12 at the position corresponding to the diffusion region 7 and is connected with the diffusion region 7.

A bit line 13A is provided with a predetermined pattern above the first interlayer insulating film 12 and the bit contact plug 11A. This bit line 13A is electrically connected with the diffusion region 7 via the bit contact plug 11A.

A second interlayer insulating film 14 is provided on the first interlayer insulating film 12 so as to cover the bit line 13A. In addition, the cylinder stopper nitride film 15 and the first cylinder interlayer insulating film 16 are provided on the second interlayer insulating film 14 in this order. In the second interlayer insulating film 14, the cylinder stopper nitride film 15, and the first cylinder interlayer insulating film 16, a capacitance contact plug 18A is provided by penetrating the films at the position corresponding to the bit line 13A and is electrically connected with the bit line 13A.

The second cylinder interlayer insulating film 17 and the third interlayer insulating film 26 are provided in this order on the first cylinder interlayer insulating film 16 and the capacitance contact plug 18A. In the second cylinder interlayer insulating film 17 and the third interlayer insulating film 26, a through hole plug 27A is provided by penetrating the films at the position corresponding to the capacitance contact plug 18A and is connected with the capacitance contact plug 18A.

A line layer 28A with a predetermined pattern is provided above the third interlayer insulating film 26 and the through hole plug 27A. The line layer 28A is electrically connected with the bit line 13A via the capacitance contact plug 18A and the through hole plug 27A.

It should be noted that the first interlayer insulating film 12, the second interlayer insulating film 14, the cylinder stopper nitride film 15, the first cylinder interlayer insulating film 16, and the second cylinder interlayer insulating film 17 in the peripheral circuit region 29 are continuous with the first interlayer insulating film 12, the second interlayer insulating film 14, the cylinder stopper nitride film 15, the first cylinder interlayer insulating film 16, and the second cylinder interlayer insulating film 17 in the cell region 2.

Incidentally, in the conventional semiconductor memory device, the capacitance contact plug 18A is not provided in the peripheral circuit region 29, and the through hole plug 27A is provided from the upper surface of the third interlayer insulating film 26 reaching to the upper surface of the bit line 13A. For this reason, the depth of a through hole 32A for forming this through hole plug 27A deepens (i.e., the aspect ratio increases), and thus it was difficult to stably form the through hole plug 27A inside the through hole 32A.

On the other hand, in this semiconductor memory device, the capacitance contact plug 18A is provided at the position corresponding to the bit line 13A even in the peripheral circuit region 29. Moreover, this capacitance contact plug 18A is provided so that it is extended to reach sufficiently above the cylinder stopper nitride film 15. Hence, the height of the through hole plug 27A can be reduced by the length equivalent to that of this capacitance contact plug 18A. For this reason, even when the depth of the cylinder holes 19 is deepened in order to secure the cell capacity, the aspect ratio of the through hole 32A for forming the through hole plug 27A can be reduced down to a relatively low level. Thereby, the through hole plug 27A can be formed stably inside the through hole 32A, and the contact resistance between the through hole plug 27A and the lines 13A and 28A can be reduced.

In addition, since the capacitance contact plug 18A provided in the peripheral circuit region 29 penetrates the second interlayer insulating film 14, the cylinder stopper nitride film 15, and the first cylinder interlayer insulating film 16 as the capacitance contact plug 18 in the cell region 2, the capacitance contact plug 18A can be formed in parallel to the capacitance contact plug 18 in the same forming process. Accordingly, the aforementioned effects can be achieved without increasing the number of fabricating processes.

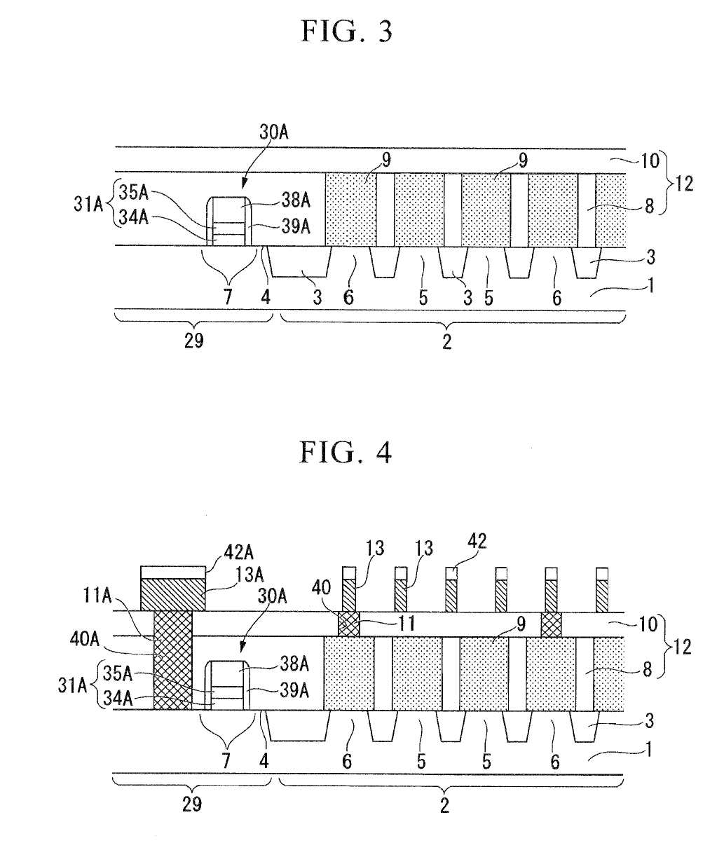

Next, the method for fabricating the semiconductor memory device of the first embodiment will be described with reference to FIGS. 3 to 11.

FIGS. 3 to 11 are longitudinal sections showing a method for fabricating the semiconductor memory device of the first embodiment according to the present invention in the order of processes. Note that FIGS. 3 to 11 correspond to the longitudinal sections, which are obtained by sectioning the semiconductor memory device in FIG. 1 along the line X-X′. Accordingly, only the diffusion regions 5 and 6 and the gate oxide film 4 are shown among the components which constitute the transistor for selection.

As shown in FIG. 3, a plurality of device isolation regions 3 are first formed in the silicon substrate 1.

Then the gate oxide film 4 is formed on the silicon substrate 1 by a thermal oxidation process or the like, and a polysilicon layer having a thickness of 70 nm is formed thereon as the gate lower electrode 34A followed by the formation of a W/WN layer having a thickness of 100 nm as a gate upper electrode 35A.

Then a mask 38A made of a nitride film which corresponds to the planar shape of the gate electrodes 31A in the cell region 2 and the peripheral circuit region 29 is formed with a thickness of 100 nm, and the polysilicon layer and the W/WN layer are patterned by employing known photolithography and dry etching techniques. Due to this process, the gate electrode 31A is obtained in both the cell region 2 and the peripheral circuit region 29.

Then the implantation of impurity ions (for example, arsenic: As) to the cell region 2 and the peripheral circuit region 29 is conducted by using the gate electrode 31A as a mask, and thereafter an annealing treatment is conducted in a nitrogen atmosphere at 900 to 1000° C. Due to this process, the implanted impurities are diffused and the diffusion regions 5, 6, and 7 are obtained.

Then side walls 39A made of a nitride film are formed with a thickness of about 30 nm on both side surfaces of the gate electrode 31A and the mask 38A made of a nitride film.

Then the interlayer insulating film 8 is formed on the silicon substrate 1 so as to cover the mask 38A made of a nitride film and the side walls 39A made of a nitride film. Subsequently, the cell contact plugs 9 are formed in the interlayer insulating film of the cell region 2 so as to penetrate the film.

Then the interlayer insulating film 10 is formed on the interlayer insulating film 8 and the cell contact plugs 9.

Due to the above processes, the first interlayer insulating film 12, which is configured from the interlayer insulating film 8 and the interlayer insulating film 10, is obtained.

As shown in FIG. 4, bit contact holes 40 and 40A are formed in the interlayer insulating film 10 of the cell region 2 at the portion corresponding to the cell contact plugs 9, which are connected with the diffusion regions 6, and in the interlayer insulating films 8 and 10 of the peripheral circuit region 29 at the portion corresponding to the diffusion region 7, respectively by penetrating the above films.

Then the bit contact plugs 11 and 11A are formed by filling in the bit contact holes 40 and 40A with the metals W/TiN/Ti.

Then the W/WN layer is formed on the first interlayer insulating film 12 and the bit contact plugs 11 and 11A. Then masks 42 and 42A made of a nitride film and which correspond to the planar shape of the bit lines 13 and 13A in the cell region 2 and the peripheral circuit region 29 are formed on this W/WN layer, and the W/WN layer is patterned by employing photolithography and etching techniques. Due to this process, the bit lines 13 and 13A are obtained in the cell region 2 and the peripheral circuit region 29, respectively.

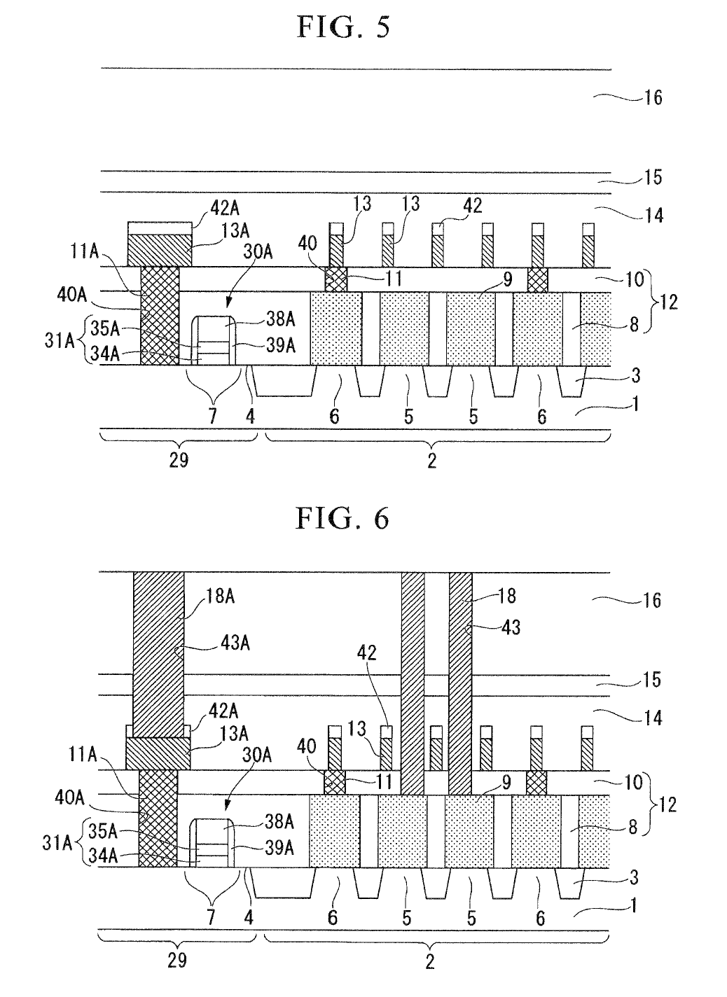

As shown in FIG. 5, the second interlayer insulating film 14 is formed on the first interlayer insulating film 12 so as to cover the bit lines 13 and 13A and the masks 42 and 42A made of a nitride film, and the cylinder stopper nitride film 15 is then formed thereon with a film thickness of about 50 nm.

Then the first cylinder interlayer insulating film 16 is formed with a thickness of 300 nm or more on the cylinder stopper nitride film 15.

In this case, thickness of the first cylinder interlayer insulating film 16 is preferably as thick as possible within the processing limit of the capacitance contact hole 43, which is formed later so as to penetrate the interlayer insulating film 10, the second interlayer insulating film 14, the cylinder stopper nitride film 15, and the first cylinder interlayer insulating film 16. Specifically, film thickness of the first cylinder interlayer insulating film 16 is preferably 300 nm to 1,200 nm.

As shown in FIG. 6, the capacitance contact hole 43 is then formed at the position corresponding to the cell contact plugs 9, which are connected with the diffusion regions 5 of the cell region 2, by using photolithography and etching techniques so as to penetrate the interlayer insulating film 10, the second interlayer insulating film 14, the cylinder stopper nitride film 15, and the first cylinder interlayer insulating film 16. Moreover, in parallel to this process, the capacitance contact hole 43A is formed at the position corresponding to the bit line 13A of the peripheral circuit region 29 so as to penetrate the second interlayer insulating film 14, the cylinder stopper nitride film 15, and the first cylinder interlayer insulating film 16. The capacitance contact plugs 18 and 18A are then formed inside the capacitance contact holes 43 and 43A. In this case, both the capacitance contact plugs 18 and 18A are formed sufficiently above the cylinder stopper nitride film 15.

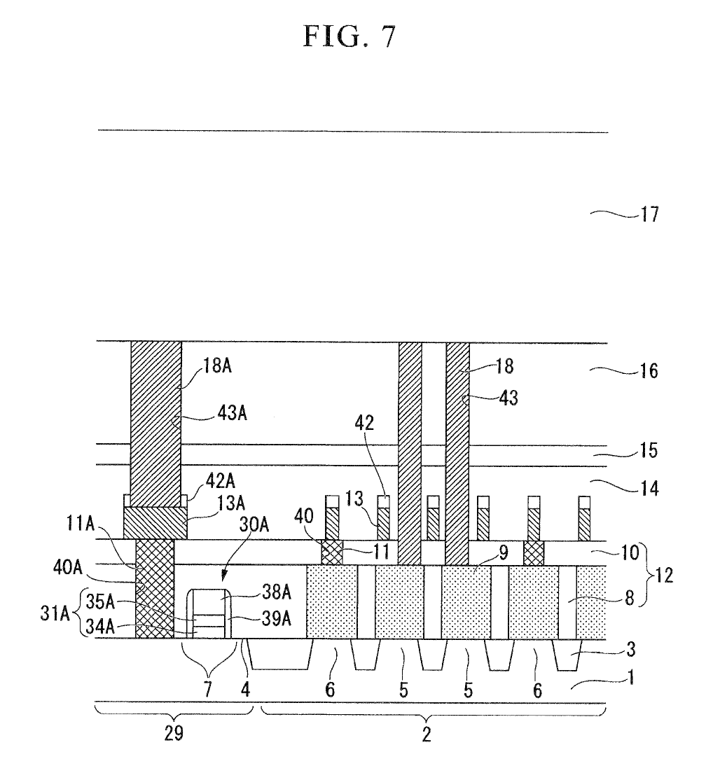

As shown in FIG. 7, the second cylinder interlayer insulating film 17 is then formed on the first cylinder interlayer insulating film 16 and the capacitance contact plugs 18 and 18A. Depth of the cylinder holes 19 formed in the later process will be determined by the film thickness of the second cylinder interlayer insulating film 17 formed in this process.

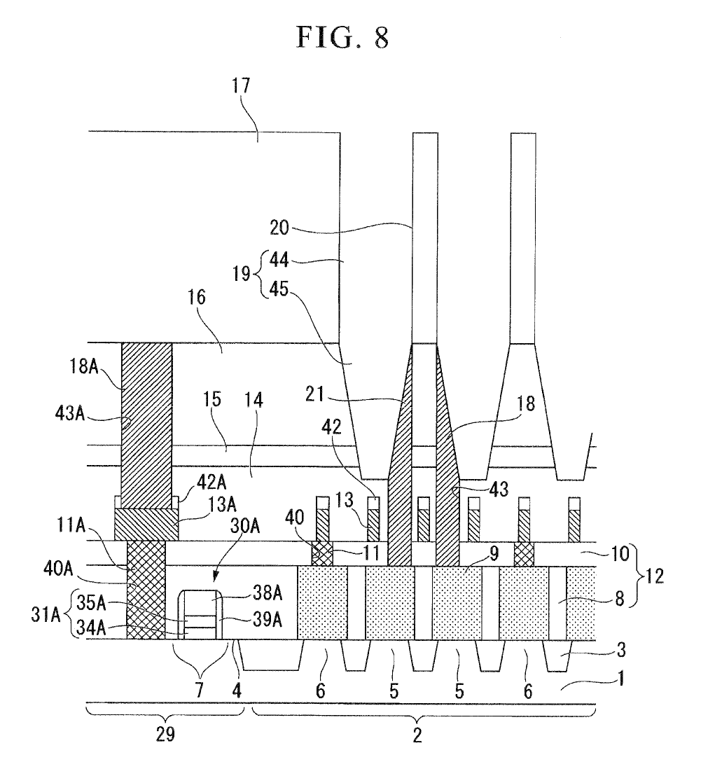

As shown in FIG. 8, the first cylinder hole 44 which penetrates the second cylinder interlayer insulating film 17 is then formed by employing photolithography and etching techniques. Due to this process, the upper end face of the capacitance contact plug 18 is exposed. When seen in plan view, the first cylinder hole 44 is formed so that the upper end face of the capacitance contact plug 18 is inscribed in an opening of the first cylinder hole 44, and also that the internal surface of the first cylinder hole 44 is almost perpendicular with respect to the upper surface of the second cylinder interlayer insulating film 17.

Subsequently, a second cylinder hole 45, which penetrates the cylinder stopper nitride film 15 and the first cylinder interlayer insulating film 16 and also enters the first interlayer insulating film 12 to some extent, is formed. In this process, the second cylinder hole 45 is formed under the condition so that the internal surface thereof will have a tapered shape.

Specifically, an etching process for achieving a tapered shape will become possible by adjusting the partial pressure ratio between the mixed gas of C₄F₆ and CF₄ and oxygen.

Due to the above processes, the cylinder hole 19 configured from the first cylinder hole 44 and the second cylinder hole 45 is obtained. In the cylinder holes 19 formed as described above, the capacitance contact plugs 18 are exposed in the second cylinder hole 45 in almost an elliptical shape with a length at least as long as the sum of the thickness of the cylinder stopper nitride film 15 and the first cylinder interlayer insulating film 16.

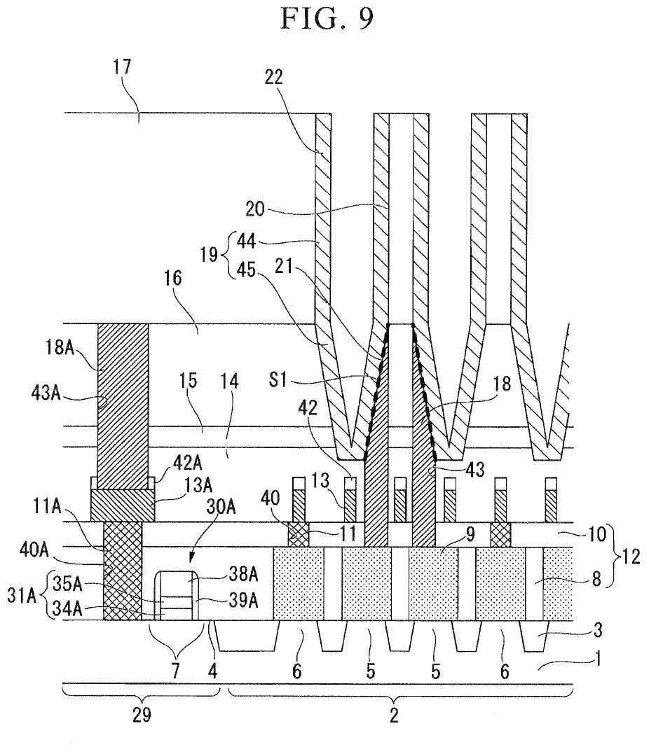

As shown in FIG. 9, a TiN layer is then formed on the internal surface of the cylinder holes 19 and on the surface of the capacitance contact plugs 18 which is exposed in the cylinder holes 19 (i.e., the exposed surface S1) with a thickness of about 20 nm, thereby forming the capacitance lower electrode 22. In the cylinder holes 19, the capacitance contact plugs 18 are exposed in almost an elliptical shape with a length at least as long as the sum of the thickness of the cylinder stopper nitride film 15 and the first cylinder interlayer insulating film 16 as described earlier. Accordingly, the capacitance contact plugs 18 have a wider exposed surface S1 in the cylinder holes 19 compared to the conventional capacitance contact plugs exposed at the bottom surface of the cylinder holes. Hence, a sufficient contact area with the capacitance lower electrode 22 formed thereon can be secured, and thus the contact resistance between the capacitance contact plugs 18 and the capacitance lower electrode 22 can be reduced. In addition, due to the wide exposed surface S1 of the capacitance contact plugs 18, it is possible to form the capacitance lower electrode 22 with a good coverability with respect to this exposed surface of the capacitance contact plugs 18. Due to the above configuration, it will be possible to achieve stable contact resistance between the capacitance contact plugs 18 and the capacitance lower electrode 22.

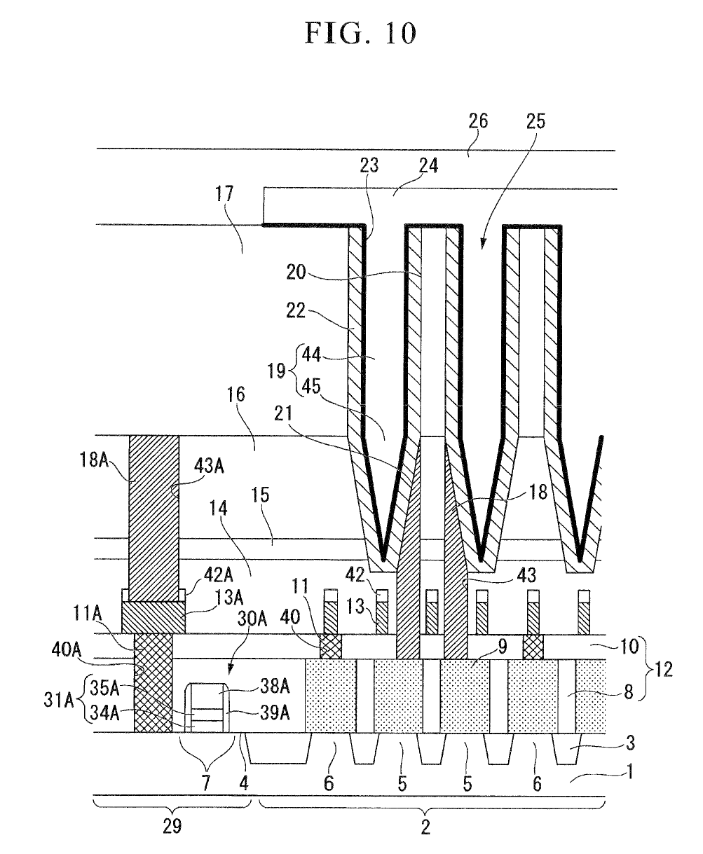

As shown in FIG. 10, an HfO₂/Al₂O₃ laminated film as the capacitance insulating film 23 is then formed on the capacitance lower electrode 22 with a thickness of about 8 nm. Subsequently, a TiN film which will become the capacitance upper electrode 24 is formed with a thickness of 15 nm on this capacitance insulating film 23 so as to fill in the cylinder holes 19.

The third interlayer insulating film 26 is then formed on the second cylinder interlayer insulating film 17 and the capacitance upper electrode 24.

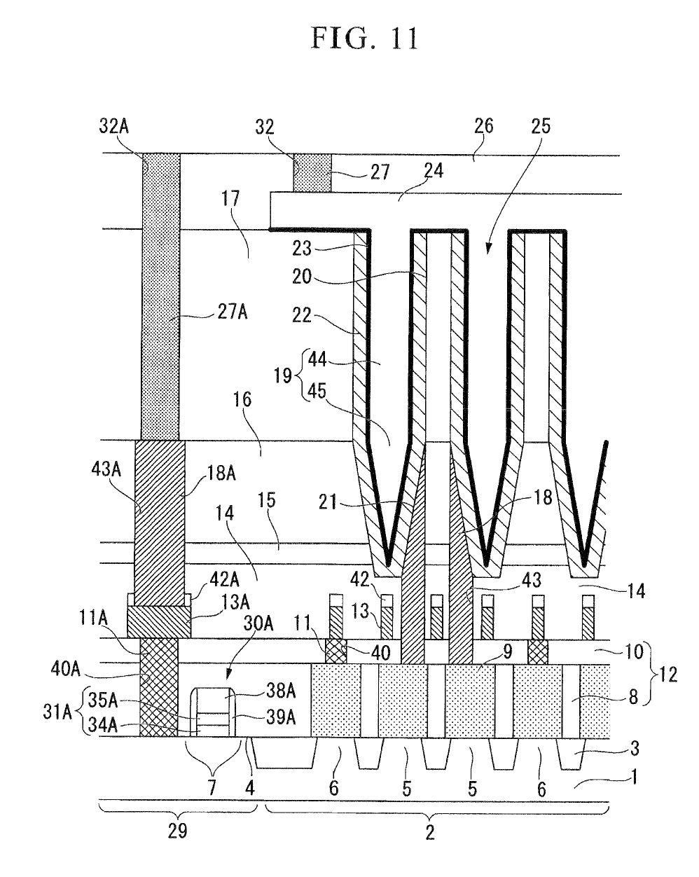

As shown in FIG. 11, the through hole 32 which penetrates the third interlayer insulating film 26 is then formed on the capacitance upper electrode 24 in the cell region 2 by employing photolithography and etching techniques. Moreover, in parallel to this process, the through hole 32A, which penetrates the third interlayer insulating film 26 and the second cylinder interlayer insulating film 17, is formed at a position corresponding to the capacitance contact plug 18A of the peripheral circuit region 29. The through hole plugs 27 and 27A are then formed inside the through holes 32 and 32A.

Incidentally, in the conventional fabrication methods, the capacitance contact plugs are not formed in the peripheral circuit region, and the through hole is formed from the upper surface of the third interlayer insulating film reaching the upper surface of the bit line. For this reason, the aspect ratio of the through hole increases and it has been difficult to stably form the through hole plug.

On the other hand, in this fabrication method, the capacitance contact plug 18A is provided at the position corresponding to the bit line 13A even in the peripheral circuit region 29. Moreover, the capacitance contact plug 18A is formed so that it is extended to reach sufficiently above the cylinder stopper nitride film 15. For this reason, the depth of the through hole 32A can be reduced by the length equivalent to this capacitance contact plug 18A, and thus the aspect ratio of the through hole 32A can be reduced down to a relatively low level even when the depth of the cylinder holes 19 deepens in order to secure the cell capacity. Accordingly, the through hole plug 27A can be formed stably inside the through hole 32A, and the contact resistance between the formed through hole plug 27A and the lines 13A and 28A can be reduced.

Lastly, an aluminum line 28 is formed on the third interlayer insulating film 26 and the through hole plugs 27 and 27A.

Due to the processes described so far, the DRAM shown in FIG. 1 will be completed.

The obtained DRAM has a low contact resistance between the capacitance contact plugs 18 and the capacitance lower electrode 22 and between the through hole plug 27A and the lines 13A and 28A, and is highly reliable.

Next, a semiconductor memory device of a second embodiment and a fabrication method thereof will be described.

It should be noted that in the second embodiment, descriptions on the same configuration as that in the aforementioned first embodiment will be omitted.

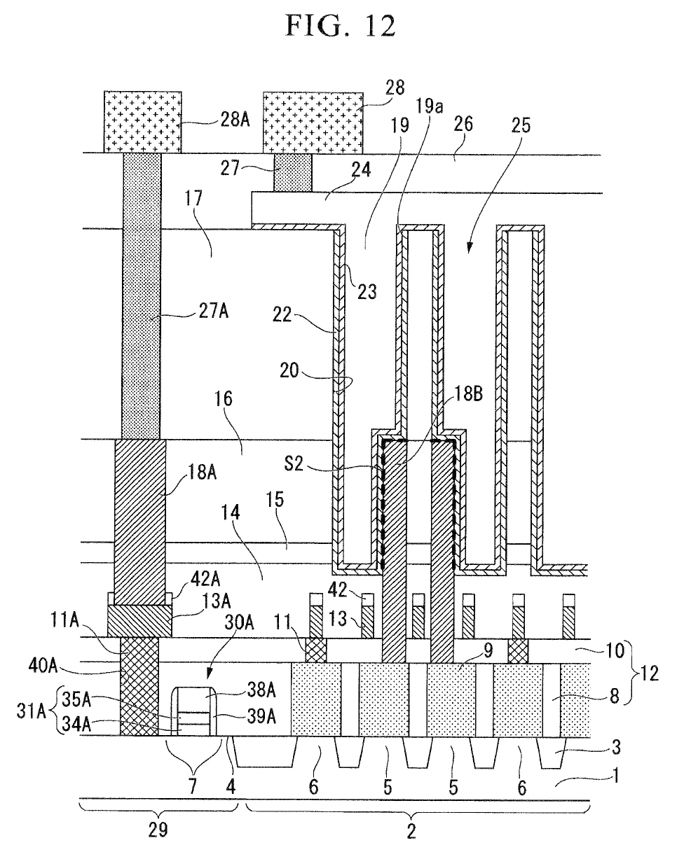

FIG. 12 is a longitudinal section showing a semiconductor memory device according to the second embodiment of the present invention.

The semiconductor memory device of the second embodiment has the same configuration as that of the first embodiment except that the internal surface of the cylinder holes 19 are provided so as to be perpendicular with respect to the upper surface of the second cylinder interlayer insulating film 17, not only in the second cylinder interlayer insulating film 17, but also in the second interlayer insulating film 14, the cylinder stopper nitride film 15, and the first cylinder interlayer insulating film 16.

In other words, in the semiconductor memory device of the second embodiment, the cylinder holes 19 are provided by penetrating the cylinder stopper nitride film 15, the first cylinder interlayer insulating film 16, and the second cylinder interlayer insulating film 17. Note that the cylinder holes 19 in this embodiment enter the second interlayer insulating film 14 to some extent. In each of these films, the internal surface of the cylinder holes 19 is almost perpendicular with respect to the upper surface of the second interlayer insulating film 17.

In addition, the capacitance contact plug 18B is protruded from the bottom portion of the cylinder holes 19 with a height at least as long as the sum of the thickness of the cylinder stopper nitride film 15 and the first cylinder interlayer insulating film 16.

Moreover, on the internal surface of the cylinder holes 19 and on the surface of the capacitance contact plug 18B protruded from the bottom surface of the cylinder holes 19 (exposed surface S2), the capacitance lower electrode 22 and the capacitance insulating film 23 are formed in this order. The capacitance upper electrode 24 is provided on this capacitance insulating film 23 so as to fill in the cylinder holes 19. Of these, the capacitance lower electrode 22 is electrically connected with the diffusion regions 5 via the capacitance contact plugs 18 and the cell contact plugs 9, and the capacitor 25 is configured from the capacitance lower electrode 22, the capacitance insulating film 23, and the capacitance upper electrode 24.

In addition, in the semiconductor memory device of this embodiment, the capacitance contact plug 18B protrudes inside the cylinder holes 19 as described earlier with a height at least as long as the sum of the thickness of the cylinder stopper nitride film 15 and the first cylinder interlayer insulating film 16. Accordingly, the capacitance contact plug 18B has a wider exposed surface S2 compared to the conventional capacitance contact plugs exposed at the bottom surface of the cylinder holes.

Hence, sufficient contact area with the capacitance lower electrode 22 formed thereon can be secured, and thus the contact resistance between the capacitance contact plug 18B and the capacitance lower electrode 22 can be reduced. In addition, due to the wide exposed surface S2 of the capacitance contact plugs 18B, it is possible to form the capacitance lower electrode 22 with a good coverability with respect to this exposed surface of the capacitance contact plug 18B. Due to the above configuration, it will be possible to achieve a stable contact resistance between the capacitance contact plug 18B and the capacitance lower electrode 22.

Also in this second embodiment, the capacitance contact plug 18A is provided at the position corresponding to the bit line 13A in the peripheral circuit region 29. Moreover, this capacitance contact plug 18A is provided so that it is extended to reach sufficiently above the cylinder stopper nitride film 15. In this configuration, it is possible to reduce the height of the through hole plug 27A by the length equivalent to this capacitance contact plug 18A. For this reason, even when the depth of the cylinder holes 19 deepens in order to secure the cell capacity, the aspect ratio of the through hole 32A for forming the through hole plug 27A can be reduced down to a relatively low level. Thereby, the through hole plug 27A can be formed stably inside the through hole 32A, and the contact resistance between the through hole plug 27A and the lines 13A and 28A can be reduced.

In addition, since the capacitance contact plug 18A provided in the peripheral circuit region 29 penetrates the second interlayer insulating film 14, the cylinder stopper nitride film 15, and the first cylinder interlayer insulating film 16 as the capacitance contact plug 18 in the cell region 2, the capacitance contact plug 18A can be formed in parallel to this capacitance contact plug 18 in the same forming process. Accordingly, the aforementioned effects can be achieved without increasing the number of fabricating processes.

Next, the method for fabricating the semiconductor memory device of the second embodiment will be described.

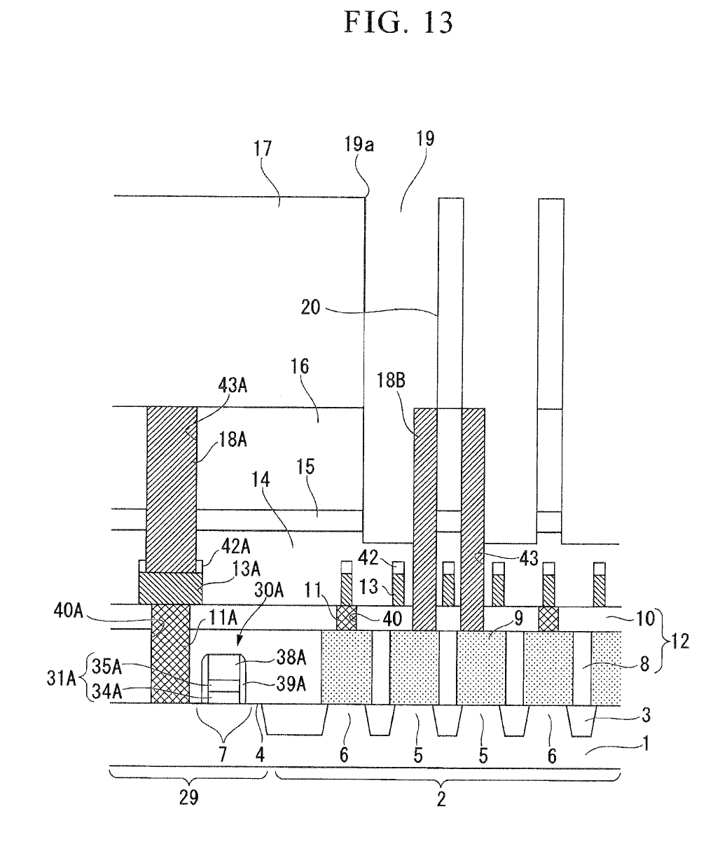

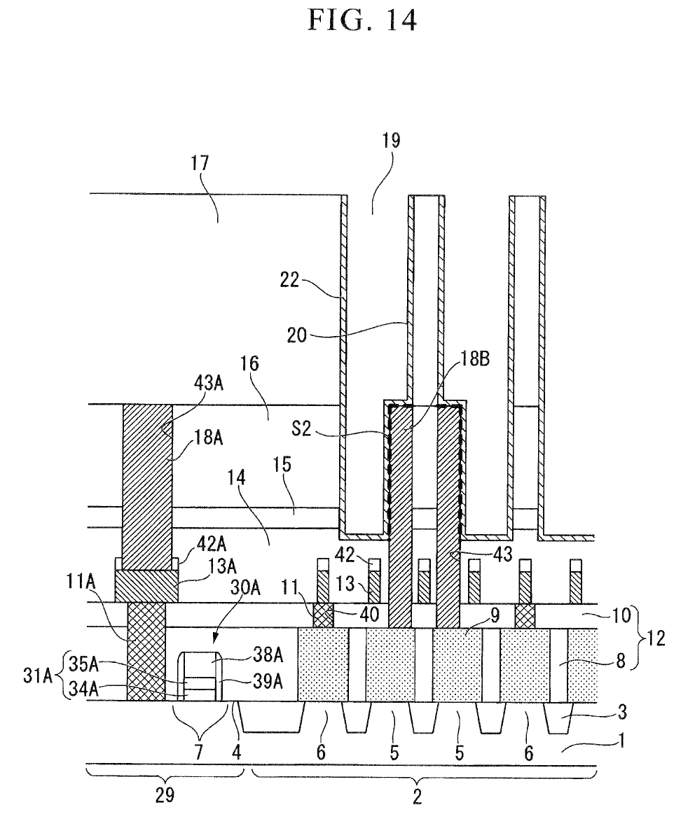

FIGS. 13 and 14 are longitudinal sections showing the order of processes of a method for fabricating the semiconductor memory device of the second embodiment.

Since the fabrication method of the second embodiment has almost identical processes to those of the fabrication method of the first embodiment until the process for forming the second cylinder interlayer insulating film shown in FIG. 7, descriptions on the method are omitted.

In other words, after forming the second cylinder interlayer insulating film 14 as shown in FIG. 7, the cylinder holes 19 which penetrate the cylinder stopper nitride film 15, the first cylinder interlayer insulating film 16, and the second cylinder interlayer insulating film 17, and which further enter the second interlayer insulating film 14 to some extent, are formed by employing photolithography and etching techniques as shown in FIG. 13. The cylinder holes 19 are formed in a position so that the upper end face of the capacitance contact plug 18B is inscribed in the opening 19a of the cylinder hole 19 when seen in plan view. Additionally, the dry etching process is carried out under conditions where the cylinder holes 19 are formed so that their internal surface is almost perpendicular to the upper surface of the second cylinder interlayer insulating film 17, and also the etching rate for the respective interlayer insulating films 14, 16, and 17, and for the cylinder stopper nitride film 15 is sufficiently higher than the etching rate for the capacitance contact plug 18B. Due to the above processes, the capacitance contact plug 18B remains unchanged so as to protrude in the cylinder holes 19 with a height at least as long as the sum of the thickness of the cylinder stopper nitride film 15 and the first cylinder interlayer insulating film 16.

As shown in FIG. 14, a TiN layer is then formed on the internal surface of the cylinder holes 19 and on the surface of the capacitance contact plug 18B which is protruding from the bottom surface of the cylinder holes 19 (i.e., the exposed surface S2) with a thickness of about 20 nm, thereby forming the capacitance lower electrode 22.

Thereafter, as the processes of the first embodiment shown in FIGS. 10 and 11, the capacitance insulating film 23, the capacitance upper electrode 24, the third interlayer insulating film 26, the through hole plugs 27 and 27A, and the line layers 28 and 28A are formed.

Due to the processes described so far, the DRAM shown in FIG. 12 will be completed.

The obtained DRAM has a low contact resistance between the capacitance contact plugs 18 and the capacitance lower electrode 22 and between the through hole plug 27A and the lines 13A and 28A, and is highly reliable.

Next, a semiconductor memory device of a third embodiment and a fabrication method thereof will be described.

It should be noted that in the third embodiment, descriptions on the same configurations as those in the aforementioned first and second embodiments will be omitted.

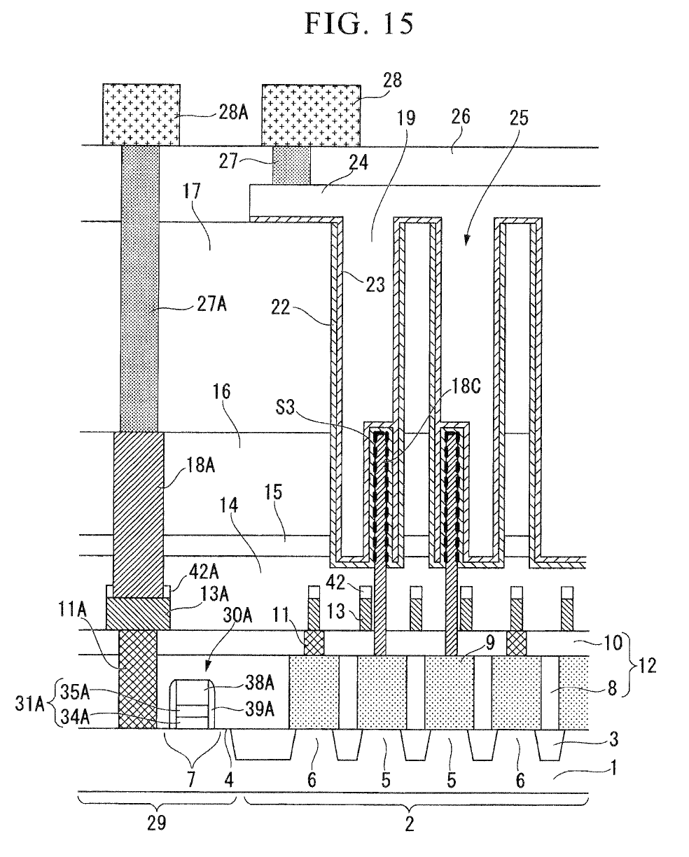

FIG. 15 is a longitudinal section showing a semiconductor memory device according to the third embodiment of the present invention.

The semiconductor memory device of the third embodiment is the same as that of the second embodiment except that the bit lines 13 have a different pitch, and that the upper end face of a capacitance contact plug 18C is positioned even further inside than the opening 19a of the cylinder holes 19 when seen in plan view.

In other words, in the semiconductor memory device of the third embodiment, the cylinder holes 19 are provided by penetrating the cylinder stopper nitride film 15, the first cylinder interlayer insulating film 16, and the second cylinder interlayer insulating film 17. Note that the cylinder holes 19 in this embodiment enter the second interlayer insulating film 14 to some extent. In each of these films, the internal surface of the cylinder holes 19 is almost perpendicular with respect to the upper surface of the second interlayer insulating film 17.

In addition, the capacitance contact plug 18C protrudes from the bottom portion of the cylinder holes 19 with a height at least as long as the sum of the thickness of the cylinder stopper nitride film 15 and the first cylinder interlayer insulating film 16. In this third embodiment, the capacitance contact plug 18C is provided so that the upper end face thereof is positioned even further inside than the opening 19a of the cylinder holes 19 when seen in plan view, and the outer peripheral surface thereof and the internal surface of the cylinder holes 19 are separated from each other.

Moreover, on the internal surface of the cylinder holes 19 and on the surface of the capacitance contact plug 18C protruded from the bottom surface of the cylinder holes 19 (exposed surface S3), the capacitance lower electrode 22 and the capacitance insulating film 23 are formed in this order. The capacitance upper electrode 24 is provided on this capacitance insulating film 23 so as to fill in the cylinder holes 19. Of these, the capacitance lower electrode 22 is electrically connected with the diffusion regions 5 via the capacitance contact plugs 18 and the cell contact plugs 9, and the capacitor 25 is configured from the capacitance lower electrode 22, the capacitance insulating film 23, and the capacitance upper electrode 24.

In addition, in the semiconductor memory device of this embodiment, the capacitance contact plug 18C protrudes inside the cylinder holes 19 as described earlier with a height at least as long as the sum of the thickness of the cylinder stopper nitride film 15 and the first cylinder interlayer insulating film 16. Accordingly, the capacitance contact plug 18C has a wider exposed surface S3 inside the cylinder holes 19 compared to the conventional capacitance contact plugs exposed at the bottom surface of the cylinder holes. Especially in the third embodiment, since the outer peripheral surface of the capacitance contact plug 18C is separated from the internal surface of the cylinder holes 19, almost the entire circumference of the portion protruding from the bottom portion of the cylinder holes 19 is covered by the capacitance upper electrode 24. Hence, sufficient a contact area with the capacitance lower electrode 22 can be secured, and thus the contact resistance between the capacitance contact plug 18C and the capacitance lower electrode 22 can be reduced. In addition, due to the wide exposed surface S3 of the capacitance contact plugs 18C, it is possible to form the capacitance lower electrode 22 with a good coverability with respect to this exposed surface S3 of the capacitance contact plug 18C. Due to the above configuration, it will be possible to achieve stable contact resistance between the capacitance contact plug 18C and the capacitance lower electrode 22.

Also in this embodiment, the capacitance contact plug 18A is provided at the position corresponding to the bit line 13A in the peripheral circuit region 29. Moreover, this capacitance contact plug 18A is provided so that it is extended to reach sufficiently above the cylinder stopper nitride film 15. According to this configuration, it is possible to reduce the height of the through hole plug 27A by the length equivalent to this capacitance contact plug 18A. For this reason, even when the depth of the cylinder holes 19 deepens in order to secure the cell capacity, the aspect ratio of the through hole 32A for forming the through hole plug 27A can be reduced down to a relatively low level. Thereby, the through hole plug 27A can be formed stably inside the through hole 32A, and the contact resistance between the through hole plug 27A and the lines 13A and 28A can be reduced.

In addition, since the capacitance contact plug 18A provided in the peripheral circuit region 29 penetrates the second interlayer insulating film 14, the cylinder stopper nitride film 15, and the first cylinder interlayer insulating film 16 as the capacitance contact plug 18 in the cell region 2, the capacitance contact plug 18A can be formed in parallel to this capacitance contact plug 18 in the same forming process. Accordingly, the aforementioned effects can be achieved without increasing the number of fabricating processes.

Next, the method for fabricating the semiconductor memory device of the third embodiment will be described.

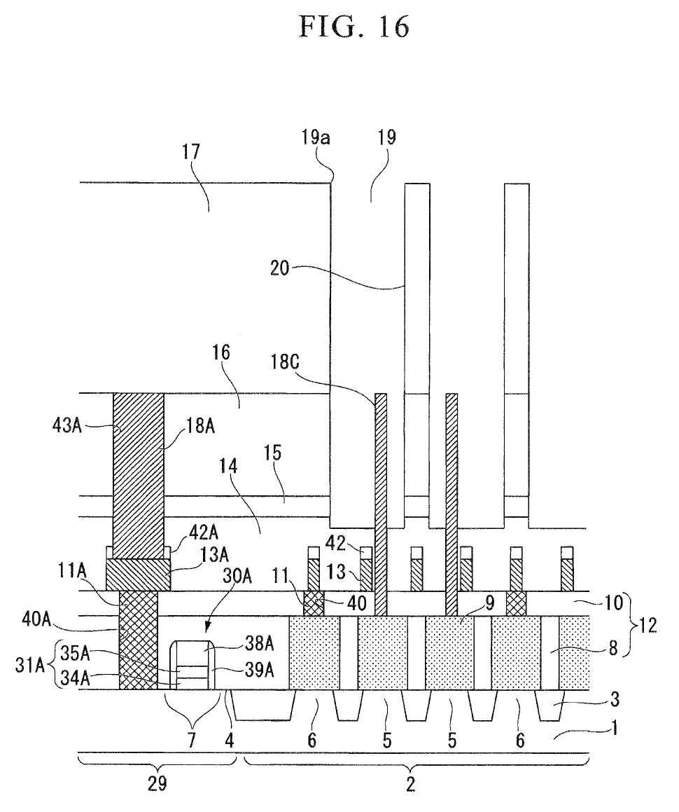

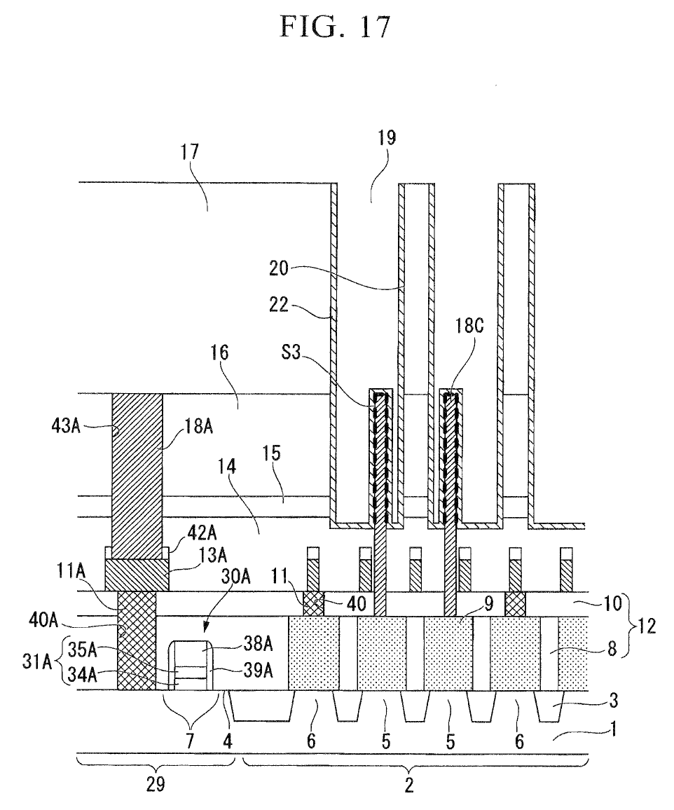

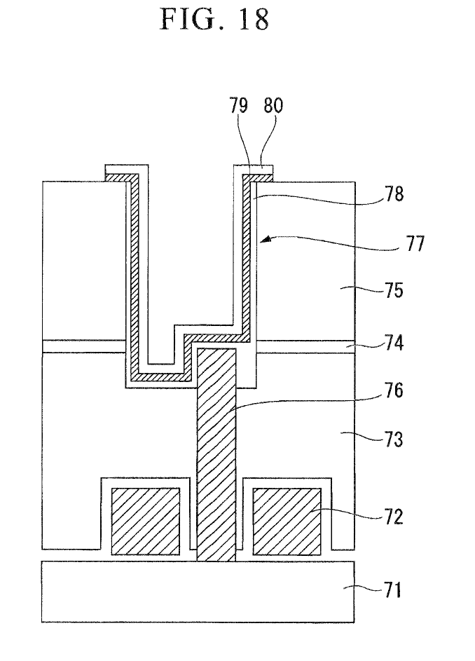

FIGS. 16 and 17 are longitudinal sections showing a method for fabricating the semiconductor memory device of the third embodiment in the order of processes.

Since the fabrication method of the third embodiment has almost identical processes to those of the fabrication method of the first embodiment until the process for forming the second cylinder interlayer insulating film shown in FIG. 7, descriptions on the method are omitted.

In other words, after forming the second cylinder interlayer insulating film 17 as shown in FIG. 7, the cylinder holes 19, which penetrate the cylinder stopper nitride film 15, the first cylinder interlayer insulating film 16, and the second cylinder interlayer insulating film 17, and which further enter the second interlayer insulating film 14 to some extent, are formed by employing photolithography and etching techniques as shown in FIG. 16. The cylinder holes 19 are formed so that the upper end face of the capacitance contact plug 18C is positioned even further inside than the opening 19a of the cylinder holes 19 when seen in plan view. Additionally, the dry etching process is carried out under conditions where the cylinder holes 19 are formed so that their internal surface is almost perpendicular to the upper surface of the second cylinder interlayer insulating film 17, and also the etching rate for the respective interlayer insulating films 14, 16, and 17, and for the cylinder stopper nitride film 15 is sufficiently higher than the etching rate for the capacitance contact plug 18C. Due to the above processes, the capacitance contact plug 18C remains unchanged so as to protrude in the formed cylinder holes 19 with a height at least as long as the sum of the thickness of the cylinder stopper nitride film 15 and the first cylinder interlayer insulating film 16.

As shown in FIG. 17, a TiN layer is then formed on the internal surface of the cylinder holes 19 and on the surface of the capacitance contact plug 18C which protrudes from the bottom surface of the cylinder holes 19 with a thickness of about 20 nm, thereby forming the capacitance lower electrode 22.

Thereafter, as the processes of the first embodiment shown in FIGS. 10 and 11, the capacitance insulating film 23, the capacitance upper electrode 24, the third interlayer insulating film 26, the through hole plugs 27 and 27A, and the line layers 28 and 28A are formed.

Due to the processes described so far, the DRAM shown in FIG. 15 will be completed.

The obtained DRAM has low contact resistance between the through hole plug 27A and the lines 13A and 28A. Moreover, especially in the third embodiment, since almost the entire circumference of the capacitance contact plug 18C protruding from the bottom portion of the cylinder holes 19 is covered by the capacitance lower electrode 22, the contact resistance between the capacitance contact plug 18C and the capacitance lower electrode 22 will be further reduced. Therefore a highly reliable DRAM is obtained.

In the present embodiment, materials constituting the respective components which configuring the semiconductor memory device, film thickness, and forming methods are merely one example, and they can be modified appropriately within the range which does not depart from the scope of the present invention.

For example, other than TiN, other metals such as W and Pt may be used as materials for the capacitance lower electrode 22 and the capacitance upper electrode 24.

Moreover, other than the HfO₂/Al₂O₃ laminated film, ZrO, STO, or the like may be used as the capacitance insulating film 23.

### INDUSTRIAL APPLICABILITY

Application examples of the present invention include a DRAM and a consolidated LSI, which includes a DRAM.

1. A semiconductor memory device comprising:
a cylinder hole extended in a thickness direction of an insulating film;
a capacitor configured from a lower electrode, which is formed on an inner surface of the cylinder hole, and an upper electrode, which is formed on a surface of the lower electrode via a capacitance insulating film; and
a capacitance contact plug which is embedded in the insulating film and a portion thereof is exposed inside the cylinder hole so as to be electrically connected with the lower electrode due to the lower electrode covering a surface of this exposed portion,
wherein the capacitance contact plug is provided by the portion, which is exposed inside the cylinder hole, being extended from a bottom portion side towards an upper portion side of the cylinder hole.

2. The semiconductor memory device according to claim 1, wherein the cylinder hole has a tapered surface in an internal surface thereof and an end face of the capacitance contact plug is exposed along the tapered surface.

3. The semiconductor memory device according to claim 2, wherein the end face of the capacitance contact plug is exposed throughout from one end portion of the tapered surface to another.

4. The semiconductor memory device according to claim 2, wherein the end face of the capacitance contact plug is inscribed in an opening of the cylinder hole when seen in plan view.

5. The semiconductor memory device according to claim 1, wherein the portion, which is exposed inside the cylinder hole, is protruding from a bottom portion of the cylinder hole.

6. The semiconductor memory device according to claim 5, wherein the end face of the capacitance contact plug is disposed further inside than the opening of the cylinder hole when seen in plan view.

7. The semiconductor memory device according to claim 1, further comprising:
a peripheral circuit region, which includes, around a region where the capacitor is provided, a transistor for a peripheral circuit and a first line that are embedded in the insulating film and a second line arranged on the insulating film,
wherein the peripheral circuit region includes a contact plug, which is provided in the same forming process as a process for forming the capacitance contact plug, on the first line.

8. The semiconductor memory device according to claim 1,
wherein the insulating film includes an etching stopper film, which controls a position to stop an etching process when forming the cylinder hole by the etching process, and
the capacitance contact plug intersects with the etching stopper film and is extended in a surface side of the insulating film.

9. A method for fabricating a semiconductor memory device which is a method for fabricating a semiconductor memory device including a cylinder hole extended in a thickness direction of an insulating film, a capacitor configured from a lower electrode, which is formed on an inner surface of the cylinder hole, and an upper electrode, which is formed on a surface of the lower electrode via a capacitance insulating film, and a capacitance contact plug which is embedded in the insulating film and a portion thereof is exposed inside the cylinder hole so as to be electrically connected with the lower electrode due to the lower electrode covering a surface of this exposed portion, the method comprising:
forming an interlayer insulating film, which is provided on a semiconductor substrate, an etching stopper film, which controls a position to stop an etching process when forming the cylinder hole by the etching process, and, on a first cylinder interlayer insulating film, the capacitance contact plug, which penetrates these films;
forming a second cylinder interlayer insulating film on the first cylinder interlayer insulating film and on the capacitance contact plug;
forming a first cylinder hole in a region containing a portion which corresponds to the capacitance contact plug of the second cylinder interlayer insulating film by subjecting the region to an etching process to penetrate so that an internal surface of the first cylinder hole is almost perpendicular to a surface of the second cylinder interlayer insulating film, and exposing an end face of the capacitance contact plug; and
forming a second cylinder hole which has a tapered internal surface so as to be continuous with the first cylinder hole by at least subjecting the etching stopper film, the first cylinder interlayer insulating film, and the capacitance contact plug to an etching process, and exposing the end face of the capacitance contact plug along the tapered internal surface.

10. A method for fabricating a semiconductor memory device which is a method for fabricating a semiconductor memory device including a cylinder hole extended in a thickness direction of an insulating film, a capacitor configured from a lower electrode, which is formed on an inner surface of the cylinder hole, and an upper electrode, which is formed on a surface of the lower electrode via a capacitance insulating film, and a capacitance contact plug which is embedded in the insulating film and a portion thereof is exposed inside the cylinder hole so as to be electrically connected with the lower electrode due to the lower electrode covering a surface of this exposed portion, the method comprising:
forming an interlayer insulating film, which is provided on a semiconductor substrate, an etching stopper film, which controls a position to stop an etching process when forming the cylinder hole by the etching process, and, on a first cylinder interlayer insulating film, the capacitance contact plug, which penetrates these films;
forming a second cylinder interlayer insulating film on the first cylinder interlayer insulating film and on the capacitance contact plug; and
forming the cylinder hole at least in the etching stopper film, the first cylinder interlayer insulating film, and in a region containing a portion which corresponds to the capacitance contact plug of the second cylinder interlayer insulating film by an etching process to penetrate these films under a condition where an etching rate for the respective interlayer insulating films and for the etching stopper film is higher than an etching rate for the capacitance contact plug, and making the portion of the cylinder hole protrude from a bottom portion of the cylinder hole.

11. The method for fabricating a semiconductor memory device according to claim 9, wherein at least one of the first cylinder interlayer insulating film and the second cylinder interlayer insulating film is formed into a laminated structure.

12. The method for fabricating a semiconductor memory device according to claim 9 which is a method for producing a semiconductor memory device including a transistor for peripheral circuit and a first line, which are embedded in the insulating film, and a second line arranged on the insulating film, around a region where the capacitor is formed, the method further comprising
forming a contact plug in parallel to the step for forming the capacitance contact plug in portions corresponding to the interlayer insulating film of the peripheral circuit region, the etching stopper film, and a bit line of the first cylinder interlayer insulating film so that the contact plug penetrates these films.

13. The semiconductor memory device according to claim 3, wherein the end face of the capacitance contact plug is inscribed in an opening of the cylinder hole when seen in plan view.

14. The semiconductor memory device according to claim 2, further comprising:
a peripheral circuit region, which includes, around a region where the capacitor is provided, a transistor for a peripheral circuit and a first line that are embedded in the insulating film and a second line arranged on the insulating film,
wherein the peripheral circuit region includes a contact plug, which is provided in the same forming process as a process for forming the capacitance contact plug, on the first line.

15. The semiconductor memory device according to claim 3, further comprising:
a peripheral circuit region, which includes, around a region where the capacitor is provided, a transistor for a peripheral circuit and a first line that are embedded in the insulating film and a second line arranged on the insulating film,
wherein the peripheral circuit region includes a contact plug, which is provided in the same forming process as a process for forming the capacitance contact plug, on the first line.

16. The semiconductor memory device according to claim 4, further comprising:
a peripheral circuit region, which includes, around a region where the capacitor is provided, a transistor for a peripheral circuit and a first line that are embedded in the insulating film and a second line arranged on the insulating film,
wherein the peripheral circuit region includes a contact plug, which is provided in the same forming process as a process for forming the capacitance contact plug, on the first line.

17. The semiconductor memory device according to claim 5, further comprising:
a peripheral circuit region, which includes, around a region where the capacitor is provided, a transistor for a peripheral circuit and a first line that are embedded in the insulating film and a second line arranged on the insulating film,
wherein the peripheral circuit region includes a contact plug, which is provided in the same forming process as a process for forming the capacitance contact plug, on the first line.

18. The semiconductor memory device according to claim 6, further comprising:
a peripheral circuit region, which includes, around a region where the capacitor is provided, a transistor for a peripheral circuit and a first line that are embedded in the insulating film and a second line arranged on the insulating film,
wherein the peripheral circuit region includes a contact plug, which is provided in the same forming process as a process for forming the capacitance contact plug, on the first line.

19. The semiconductor memory device according to claim 2,
wherein the insulating film includes an etching stopper film, which controls a position to stop an etching process when forming the cylinder hole by the etching process, and
the capacitance contact plug intersects with the etching stopper film and is extended in a surface side of the insulating film.

20. The semiconductor memory device according to claim 3,
wherein the insulating film includes an etching stopper film, which controls a position to stop an etching process when forming the cylinder hole by the etching process, and
the capacitance contact plug intersects with the etching stopper film and is extended in a surface side of the insulating film.
